(19) United States
(12) Patent Application Publication
(10) Pub. No.: US 2006/0231828 A1
(43) Pub. Date: Oct. 19, 2006

(54) Light-emitting diode

(76) Inventors: Margaretha Maria De Kok-Van Breemen, Eindhoven (NL); Michael Buechel, Eindhoven (NL); Suzanna H.P.M De Winter, Eindhoven (NL); Simore Irene Elisabeth Vulto, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/567,222

(22) PCT Filed: Jul. 29, 2004
(86) PCT No.: PCT/IB04/51324

§ 371 Date: Feb. 3, 2006

(51) Int. Cl. H01L 29/08

(52) U.S. Cl. 257/40

(57) ABSTRACT

The invention pertains to a light-emitting diode (LED) comprising layers of an anode, an acidic hole conducting-injecting material, a light-emitting polymer, and a cathode, characterized in that the hole conducting-injecting material comprises a poly(3,4-ethylenedioxythiophene poly(styrenesulfonate) (PEDOT), which is obtainable by at least partially neutralizing the PEDOT with an anion that is comprised or formed from a sodium or potassium compound, and the light-emitting material comprises a light-emitting p-arylenevinylene polymer (PAV). The invention further relates to a method for increasing the efficiency of said light-emitting diode.

The invention pertains to a light-emitting diode (LED) comprising layers of an anode, an acidic hole conducting-injecting material, a light-emitting polymer, and a cathode.

Most poly-LEDs (polymer-based LEDs) consist of two polymer layers sandwiched between two electrode materials: one hole conducting-injecting material and the light-emitting polymer. The light-emitting polymer can be of the PAV type [poly(p-arylene vinylene)]. For the first function poly(3,4-ethylenedioxythiophene, PEDT), available as an aqueous dispersion thereof with polystyrene sulfonic acid (PSS) can be used. This dispersion is called PEDOT and is commercially available from HC Starck as BAYTRON® P VP CH 8000 (high ohmic) or Baytron® P VP AI 4083 (low ohmic). Because of the acidic nature of PSS the pH for a PEDOT solution of a solid content of 2.5% is below 2. The function of PSS is to keep PEDT soluble and stable in solution. In fact, the PEDT is polymerized in the presence of PSS. The PEDT is doped (oxidized) instantaneously during the polymerization. This results in a charged polymer, which is able to conduct holes. The negatively charged sulfonate groups act as counter ion balance for the doped, positively charged PEDT units (in general one on three to four units in PEDT are positively doped).

Such LEDs are well known in the art, for instance see US 2003/0011306, which is incorporated by reference.

There is a continuous need for improving the efficacy of such LEDs, in particular for improving the brightness of the displays containing these LEDs. In U.S. Pat. No. 6,284,435 it was proposed to improve the quantum efficiency by adding highly polarizable organic anion surfactant additives, such as lithium salts of various ether sulfate anionic surfactants.

We have now found that the efficacy of LEDs comprising PEDOT as the hole conducting-injection material and PAV-type polymers as light-emitting polymers can considerably be improved by a simple and cheap method without the need of using expensive surfactants or other organic materials. According to this invention increased brightness levels can be obtained at higher voltages (at least 10 V, preferably at least 15 V) in pulsed driving modes when at least partially neutralized PEDOT is used in combination with a PAV. Thus the invention also relates to a LED comprising pulsed mode driving means adapted for providing a voltage of at least 10 V, preferable at least 15 V. Neutralization can be effected by removal of protons from PEDOT and replacement by metal ions, for instance by addition of a base, such as a metal hydroxide, or by another material that is able to remove protons from PEDOT. The neutralization with sodium hydroxide as an example, and the structures of the polymers are given in Scheme 1.

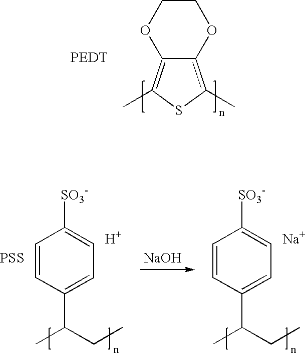

To this end the invention relates to a previously mentioned LED wherein the hole conducting-injecting material comprises a poly(3,4-ethylenedioxythiophene poly(styrenesulfonate) (PEDOT), which is obtainable by at least partially neutralizing the PEDOT with an anion that is comprised or formed from a sodium or potassium compound, and the light-emitting material comprises a light-emitting p-arylene-vinylene polymer (PAV) thereof.

The sodium or potassium compound is preferably sodium or potassium hydroxide, nitrate, carbonate, or hydrogen carbonate, and more preferably sodium hydroxide. The best results are obtained when PEDOT is neutralized to a pH of at least 3. Preferably, the pH is 3-7, more preferably 5.5-6.5. The neutralization of PEDOT can be obtained by a common base-acid reaction, for instance with sodium hydroxide, or in situ by capturing protons from PEDOT under the conditions used for removing the aqueous solvent, as is for instance the case with sodium nitrate that under these conditions forms a nitrate anion which captures a proton from PEDOT, that leaves the solution as gaseous nitric acid.

The invention further relates to a method for increasing the efficiency of a light-emitting diode (LED) comprising layers of an anode, an acidic hole conducting-injecting material, a light-emitting polymer, and a cathode, wherein the hole conducting-injecting material comprises poly(3,4-ethylenedioxythiophene poly(styrenesulfonate) (PEDOT) and the light-emitting material comprises light-emitting poly(p-arylene vinylene) (PAV), characterized in that the acidic hole conducting-injecting material is at least partially neutralized with an anion that is comprised or formed from a sodium or potassium compound.

In the drawings:

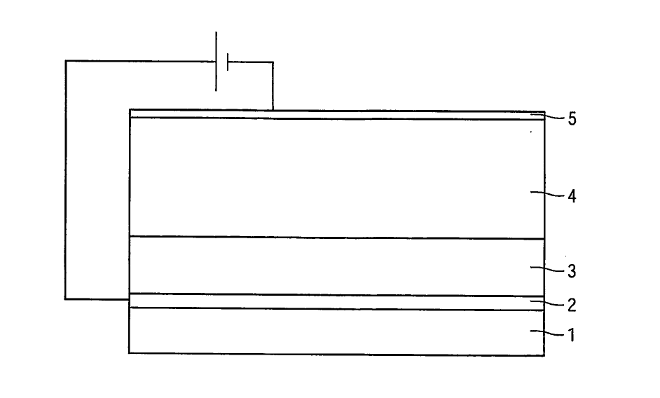

FIG. 1 shows schematically, in a cross-sectional view an embodiment of an LED in accordance with the invention.

A schematic view of a LED is given in FIG. 1. This figure shows a LED with a substrate 1, which is usually glass, an anode 2, which may be ITO, a layer 3 comprising PEDOT, a layer 4 comprising PPV, and a cathode 5.

Particularly, reference is made to patent application WO 96/08047, which discloses various materials and methods of preparation thereof, and which contents are incorporated by reference. The material for use in the conductive transparent polymer (CTP) layer is the mixture of poly-3,4-ethylenedioxythiophene and polystyrene sulfonic acid (PEDOT).

The active layer is situated between two electrode layers of electroconductive materials. At least one of said electrode layers must be transparent or translucent to the emitted light in the active layer. One of the electrode layers serves as the (positive) electrode for injecting holes into the active layer. The material of this electrode layer has a high work function and is generally formed by a layer of indium oxide or indium-tin oxide (ITO). In addition, such layers are transparent to the emitted light in the active layer. Particularly ITO is suitable because of its satisfactory electrical conductivity and high transparency. The other electrode layer serves as the (negative) electrode for injecting electrons into the active layer.

The material for this layer has a lower work function and is generally formed from a layer of, for example, indium, calcium, barium, or magnesium.

The electrode layer of ITO is provided by vacuum evaporation, sputtering, or a CVD process. This electrode layer and often also the negative electrode layer, for example, of calcium, are structured in accordance with a pattern by means of a customary photolithographic process or by partly covering it with a mask during the vacuum deposition process, which corresponds to the desired pattern for a display. In a typical example of a display, the electrodes of the first and second electrode layers have line structures, which intersect each other at right angles and hence form a matrix of separately drivable rectangular LEDs.

The rectangular LEDs constitute the pixels or picture elements of the display. If the electrodes of the first and second electrode layers are connected to an electrical source, light-emitting pixels are formed at the intersection of the electrodes. In this way a display can be formed in a simple manner. The pixel structure is not limited to a particular shape. Basically all pixel shapes are possible leading to a segmented display, e.g. for showing icons or simple figures. It should be noted that according to the present invention, apart from passive matrix structures also active matrix structures could be used.

The light-emitting polymers, which term includes homopolymers, terpolymers, copolymers, block copolymers, oligomers (including low molecular weight compounds), and the like, may be any electroluminescent material of the poly (p-arylene vinylene) (PAV) type such as poly(p-phenylene vinylene), the phenylene group of which may be substituted, as disclosed in WO 98/27136. A poly(p-phenylene vinylene) (PPV), more particular a phenyl-substituted PPV, is a preferred type of polymer to be used. PAV-type polymers contain at least two, the same or different, arylene-vinylene moieties. Thus the copolymers and the like according to this invention may further comprise other light-emitting moieties, such as fluorene or spirofluorene moieties.

Preferably, soluble conjugated polymers are used because they can be easily applied, for example in a spin-coating process or by ink jetting. Preferable solubility is improved by substituting a conjugated PPV derivative with alkyl and/or alkoxy or phenyl groups. The light emitting material may also be a doped low molecular material, such as 8-hydroxyquinolin-aluminum doped with a dye, such as quinacridone, deposited in a vacuum process.

Dependent upon the preparation of the conjugated polymer, said polymer may comprise 5 to 10% non-conjugated units. It has been found that such non-conjugated units increase the electroluminescence efficiency, which is defined by the number of photons per injected electron in the active layer.

The above-mentioned conjugated PAV derivatives can be dissolved in the customary organic solvents, for example halogenated hydrocarbons such as chloroform, and optionally substituted aromatic hydrocarbons such as toluene, xylenes, anisole, chlorobenzene, and mesitylene. Methylbenzoate and tetrahydrofurane can also be used as solvents.

The degree of polymerization of the conjugated polymer ranges between 10 and 100,000.

The layer thickness of the light emitting layer of the conjugated polymer often ranges between 10 and 250 nm, in particular between 50 and 130 nm.

The LED structure can be provided on a substrate, which is made, for example, from glass, quartz glass, ceramic, or synthetic resin material. Transistors or other electronic means may be present between the substrate and the transparent electrode forming a so-called active matrix substrate. Preferably, use is made of a translucent or transparent substrate. If a flexible electroluminescent device is desired, use is made of a transparent foil of a synthetic resin. Suitable transparent and flexible synthetic resins are, for example, polyamide, polyethylene terephthalate, polycarbonate, polyethene, and polyvinyl chloride.

The invention is illustrated by the following example.

### Efficacies of Devices in cd/A at a Given Brightness

BAYTRON® P VP CH 8000 was neutralized with hydroxides of Cs (comparison example) or Na. It was found that CsOH had no beneficial effect on the efficacy of the LED. Brightness above 100,000 cd/m2 could not be obtained in the pH range 1-7.

NaOH, on the contrary had a beneficial effect on the efficacy. The higher the pH, the higher the efficacy was found. The use of NaOH as base further made it possible to obtain LEDs with brightness above 100,000 cd/m2. At pH 4 and higher even brightness above 200,000 cd/m2 was possible.

The device used to obtain the date in the table had a standard device configuration of ITO, 200 nm PEDOT, 80 nm SY-LEP, and Ba/Al cathode. It is driven in pulsed mode, 1% pulse duty cycle at 200 Hz with a voltage indicated in the Table between brackets.

SY-LEP was commercially obtained from Covion, Germany, which is a copolymer of at least the building blocks with the following structures:

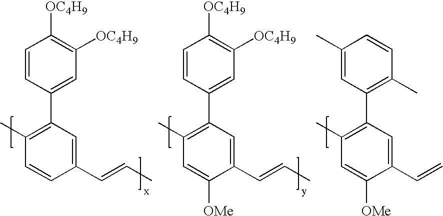

| | | Eff. (cd/A) at | Eff. (cd/A) at | Eff (cd/A) at |
|---|---|---|---|---|
| Compound | pH | 20.000 cd/m2 | 60.000 cd/m2 | 200.000 cd/m2 |
| Ref. | 1 | 10 (8.3) | 9 (12.0) | — |
| CsOH | 2 | 9 (9.0) | 8.5 (13.0) | — |
| CsOH | 3 | 7 (11.5) | 6.5 (16.0) | — |
| CsOH | 4 | 2.5-3.5 (16.0) | — | — |
| CsOH | 5 | 2.5-3.5 (16.0) | — | — |
| CsOH | 6 | 2.5-3.5 (16.5) | — | — |
| NaOH | 2 | 9.5-11 (10.0) | 8-9 (13.5) | — |
| NaOH | 3 | 11-13 (10.3) | 13-15 (14.0) | — |
| NaOH | 4 | 9-10 (12.5) | 15-17 (14.5) | 17-23 (17.5) |
| NaOH | 5 | 7.5-10 (11.5) | 11-16 (13.0) | 15-20 (16.2) |
| NaOH | 6 | 16-17 (10.5) | 20-25 (12.0) | 28-40 (15.0) |

Ref.: no addition of neutralizing compound
Eff. = efficacy

Voltages at which the indicated brightness levels are obtained are indicated between brackets.

1. A light-emitting diode (LED) comprising layers of an anode, an acidic hole conducting-injecting material, a light-emitting polymer, and a cathode, characterized in that the hole conducting-injecting material comprises a poly(3,4-ethylenedioxythiophene poly(styrenesulfonate) (PEDOT), which is obtainable by at least partially neutralizing the PEDOT with an anion that is comprised or formed from a sodium or potassium compound, and the light-emitting material comprises a light-emitting p-arylenevinylene polymer (PAV).

2. The LED of claim 1 wherein the compound is sodium or potassium hydroxide, nitrate, carbonate, or hydrogen carbonate.

3. The LED of claim 2 wherein the compound is sodium hydroxide.

4. The LED of any one of claim 1 wherein the pH is greater than 3.

5. The LED of any one of claim 1 wherein the pH is 3-7, preferably 5.5-6.5.

6. The LED of any one of claim 1 wherein the PAV is a poly(p-phenylene vinylene).

7. The LED of any one of claim 1 comprising pulsed mode driving means adapted for providing a voltage of at least 10 V, preferable at least 15 V.

8. A method of driving a LED according to claim 8 wherein the LED is pulsed mode driven at a voltage of at least 10 V, preferable at least 15 V.

9. Method for increasing the efficiency of a light-emitting diode (LED) comprising layers of an anode, an acidic hole conducting-injecting material, a light-emitting polymer, and a cathode, wherein the hole conducting-injecting material comprises poly(3,4-ethylenedioxythiophene poly(styrenesulfonate) (PEDOT) and the light-emitting material comprises poly(p-arylene vinylene) (PAV), characterized in that the acidic hole conducting-injecting material is at least partially neutralized with an anion that is comprised or formed from a sodium or potassium compound.
